(19) United States
(12) Patent Application Publication
(10) Pub. No.: US 2014/0055192 A1
(43) Pub. Date: Feb. 27, 2014

(54) SATURATION CURRENT LIMITING CIRCUIT TOPOLOGY FOR POWER TRANSISTORS

(71) Applicant: RF Micro Devices, Inc., Greensboro, NC (US)

(72) Inventors: Andrew P. Ritenour, Colfax, NC (US); Dan Schwob, Mountain View, CA (US)

(21) Appl. No.: 13/927,182

(22) Filed: Jun. 26, 2013

Related U.S. Application Data
(60) Provisional application No. 61/693,038, filed on Aug. 24, 2012.

(51) Int. Cl. H03K 17/08

(52) U.S. Cl. CPC H03K 17/08
USPC 327/436

(57) ABSTRACT

A circuit topology for limiting saturation current in power transistors is disclosed. The circuit topology includes a normally-on transistor and a normally-off transistor coupled in series. A limiter circuit is coupled between a gate of the normally-on transistor and a source of the normally-off transistor for limiting the steady-state maximum gate-to-source voltage V_{GS} of the normally-on transistor, which in turn limits the saturation current that flows through the normally-on transistor and the normally-off transistor.

### RELATED APPLICATIONS

This application claims the benefit of U.S. provisional patent application No. 61/693,038, filed Aug. 24, 2012, the disclosure of which is incorporated herein by reference in its entirety.

### FIELD OF THE DISCLOSURE

The present disclosure is related to power transistors and in particular to a circuit topology that limits saturation current.

### BACKGROUND

Conventional power transistors are vertical structures that utilize a wafer's front side for the gate and source electrodes, and utilize the wafer's backside for the drain electrode. Examples of such vertical devices include double-diffused metal oxide semiconductor (DMOS) transistors and insulated gate bipolar transistors (IGBTs) which are typically normally-off devices. As a result of the vertical structure used by conventional power transistors, increasing the current density of these devices by increasing the doping in the region between gate and drain, or by reducing the distance between gate and drain, does not have an impact on die size. In contrast, conventional gallium nitride (GaN) high electron mobility transistor (HEMT) devices are typically normally-on devices that are laterally structured with source and drain electrodes on the front side of a die substrate. In a laterally structured device, the width of the source and drain electrodes must increase to support higher current in the device. Furthermore, compared to a normally-off device, a normally-on device will exhibit triode-like behavior and the drain current will saturate at a higher drain voltage, resulting in high peak current in the device. Consequently, trade-offs between die size, on-resistance, and maximum drain current are a serious concern for lateral transistors.

FIG. 1 is a plan view of a prior art GaN HEMT device 10 having a lateral structure. The GaN HEMT device 10 has a die substrate 12 onto which a source 14 and a drain 16 are fabricated. A gate 18 has fingers that extend between the fingers of the source 14 and the drain 16. A device pitch P represents the distance between centers of adjacent pairs of fingers making up the source 14 and the drain 16. A length L represents the length of the fingers of the drain 16. A width W represents the edge-to-edge distance of individual fingers making up the source 14 and the drain 16. The width W must be large enough to handle the maximum current expected to flow through the fingers of the source 14 and the drain 16. Thus, the device pitch P is directly related to the maximum device current through the electrode width W.

FIG. 2 is a graph of on-resistance and total maximum drain current as a function of maximum current density for a constant die size for the prior art GaN HEMT device 10 of FIG. 1. A total gate width for each current density is labeled on the graph of FIG. 2. The total gate width in the graph of FIG. 2 ranges from 55 mm to 94 mm. As the maximum allowed current density in mA/mm increases, the width W of the source and drain electrodes must also increase to prevent electrode failure due to electromigration. This consequently increases the pitch P resulting in lower total gate width (top axis labeled TOTAL GATE WIDTH (mm) of FIG. 2) and higher on-resistance. As the GaN HEMT current density increases from around about 400 mA/mm to around about 800 mA/mm, the total gate width within the constant die size decreases from around about 94 mm to around about 55 mm and the on-resistance correspondingly increases from around about 85 mΩ to around about 150 mΩ. Therefore, in lateral transistors a tradeoff between on-resistance and maximum allowable current can exist. Furthermore, for some applications such as surge current protection, it is desirable to have very low on-resistance while limiting the maximum current that can flow through the transistor. For a typical normally-on transistor, these two requirements are mutually exclusive in that low on-resistance corresponds to high maximum current. As such, a need exists for a saturation current limiting circuit topology for power transistors such as the GaN HEMT device 10.

### SUMMARY

The present disclosure provides a circuit topology for limiting saturation current in power transistors. The circuit topology includes a normally-on transistor and a normally-off transistor coupled in series. A limiter circuit is coupled between a gate of the normally-on transistor and a source of the normally-off transistor for limiting the steady-state maximum gate-to-source voltage V_{GS} of the normally-on transistor, which in turn limits the saturation current that flows through the normally-on transistor and the normally-off transistor.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure, and together with the description serve to explain the principles of the disclosure.

FIG. 1 is a plan view of a prior art structure for a gallium nitride (GaN) high electron mobility transistor (HEMT).

FIG. 2 is a graph of on-resistance and total maximum current as a function of maximum current density for a constant die size for the prior art GaN HEMT device of FIG. 1.

FIG. 3 is a graph of typical output characteristics for the prior art GaN HEMT structure of FIG. 1.

FIG. 4 is a schematic of an exemplary embodiment of a circuit topology of a power transistor structure that is in accordance with the present disclosure.

### DETAILED DESCRIPTION

The embodiments set forth below represent the necessary information to enable those skilled in the art to practice the disclosure and illustrate the best mode of practicing the disclosure. Upon reading the following description in light of the accompanying drawings, those skilled in the art will understand the concepts of the disclosure and will recognize applications of these concepts not particularly addressed herein. It should be understood that these concepts and applications fall within the scope of the disclosure and the accompanying claims.

It will be understood that when an element such as a layer, region, or substrate is referred to as being “over,” “on,” “in,” or extending “onto” another element, it can be directly over, directly on, directly in, or extend directly onto the other element or intervening elements may also be present. In contrast, when an element is referred to as being “directly over,” “directly on,” “directly in,” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The present disclosure provides a circuit topology for limiting the saturation current of power transistors. In particular, the circuit topology in one application may be used to reduce on-resistance for a given die size and maximum current rating. Alternatively, in another application, the circuit topology may be used to reduce the maximum current for the same on-resistance. Both applications are useful for providing current surge protection.

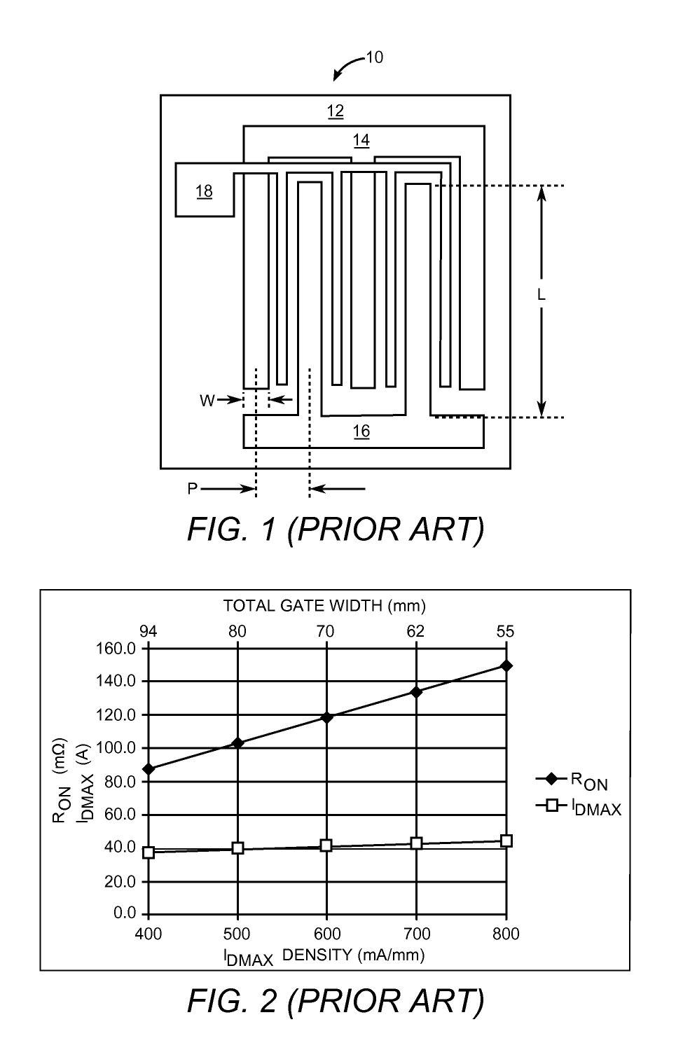

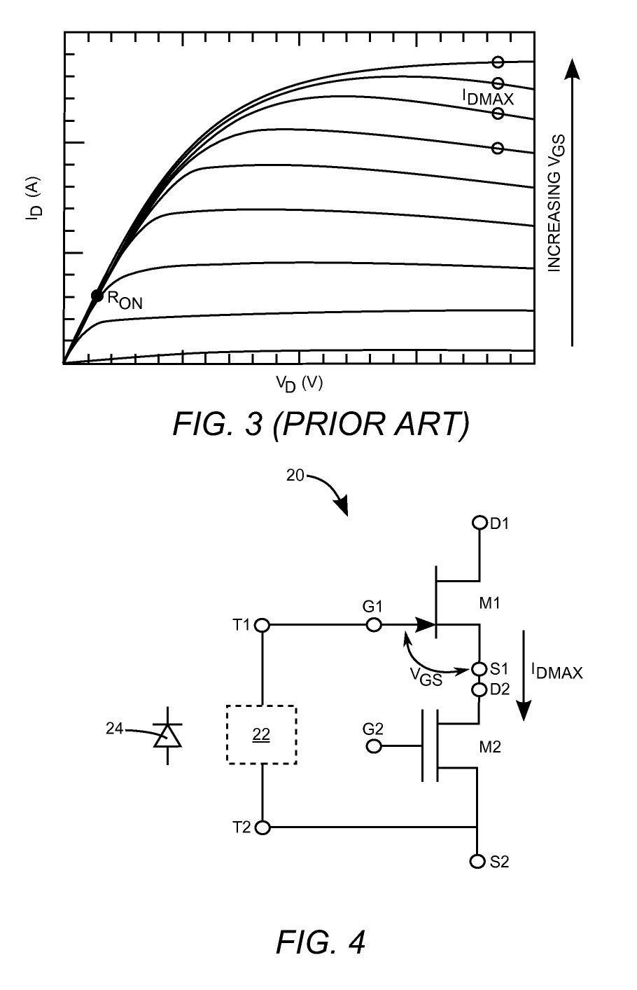

FIG. 3 is a graph of typical output characteristics for the prior art GaN HEMT 10 of FIG. 1. Notice that at low drain voltage V_{D} at around about 1 V to 2 V, the on-resistance R_{ON} represented by a solid circle is relatively insensitive to gate-to-source voltage V_{GS}. In contrast, the maximum current I_{DMAX} is strongly correlated to V_{GS} as illustrated by several values of I_{DMAX} represented by open circles. As a result, the current density of a transistor may be decreased by limiting V_{GS} to lower negative values.

FIG. 4 is a schematic of an exemplary embodiment of a circuit topology of a power transistor structure 20 that, in accordance with the present disclosure, provides saturation current limiting. The power transistor structure 20 includes a normally-on transistor M1 having a first drain D1, a first source S1, and a first gate G1. The power transistor structure 20 also includes a normally-off transistor M2 having a second drain D2, a second source S2, and a second gate G2. The normally-on transistor M1 and the normally-off transistor M2 are coupled in series. In particular, the first source S1 of the normally-on transistor M1 is coupled to the second drain D2 of the normally-off transistor M2. Further still, the first drain D1 is typically coupled to a power source (not shown) and the second source S2 is typically coupled to a return node such as ground (not shown).

In operation, the second gate G2 typically receives a control signal from a controller (not shown) that is used to switch the normally-off transistor M2 on and off. When the normally-off transistor M2 is turned on, a conventional current enters the first drain D1 and flows out of the first source S1 and into the second drain D2. The conventional current then flows out of the second source S2. In order to limit a saturation current level to a maximum current I_{DMAX}, the gate-to-source voltage V_{GS} between the first gate G1 and the first source S1 must be limited. As such, the present disclosure provides a limiter circuit 22 that is coupled between a first terminal T1 and a second terminal T2, which are coupled to the first gate G1 and the second source S2, respectively. It is to be understood that the second terminal T2 can be coupled to a common node to which the second source S2 is coupled and does not necessarily need to be coupled directly to the second source S2 to limit the gate-to-source voltage V_{GS}. Assuming the on-resistance of the normally-off transistor M2 is negligible, the maximum steady-state V_{GS} of the normally-on transistor M1 will typically be 0 V without the limiter circuit 22. A maximum steady-state V_{GS} of 0 V will in many cases allow the maximum drain current I_{DMAX} to reach a level that is potentially damaging to the power transistor structure 20 or an external circuit if the power transistor is being used for surge current protection.

The limiter circuit 22 can be made up of at least one passive circuit element such as a resistor and/or at least one active circuit element such as a diode or transistor that forces the maximum steady-state V_{GS} to be lower than 0 V. In one embodiment, the limiter circuit 22 is a diode 24. If the diode 24 is a silicon diode, the maximum steady-state V_{GS} of the normally-on transistor M1 is limited to approximately −0.7 V, which is the normal forward voltage drop for a silicon diode. Referring back to FIG. 3, a V_{GS} of −0.7 V constrains the maximum drain current I_{DMAX} to a value that is significantly lower than a value for the maximum drain current I_{DMAX} for a steady-state V_{GS} of 0 V. In one embodiment, the active circuit element is a plurality of the diodes 24 coupled in series between the first gate G1 and the second source S1 such that a total forward voltage drop of the plurality of the diodes 24 constrains the gate-to-source voltage V_{GS} of the normally-on transistor M1 to a value that limits a drain current I_{DMAX} flowing through the normally-off transistor M2 to a predetermined value when the normally-off transistor M2 is turned on. For example, fabricating the limiter circuit 22 from two silicon diodes coupled in series limits V_{GS} to approximately −1.4 V, which in turn limits the maximum drain current I_{DMAX} to an even lower value than that achieved with using just one silicon diode for limiter circuit 22.

Various other configurations of passive and active circuit elements used to make up the limiter circuit 22 can provide finer control over the limitation of the maximum drain current I_{DMAX}. Also, it is to be understood that while the embodiment of FIG. 4 employs N-type field effect transistor (FET) technology, P-type FET technology can also be employed without straying from the scope of the concepts disclosed herein.

Those skilled in the art will recognize improvements and modifications to the embodiments of the present disclosure. All such improvements and modifications are considered within the scope of the concepts disclosed herein and the claims that follow.

What is claimed is:

1. A saturation current limiting circuit topology for power transistors comprising:
a normally-on transistor having a first source, a first drain, and a first gate;
a normally-off transistor having a second source, a second drain, and a second gate, wherein the normally-on transistor and the normally-off transistor are coupled in series having the first source coupled to the second drain; and
a limiter circuit coupled between the first gate and the second source for limiting a gate-to-source voltage of the normally-on transistor.

2. The circuit topology of claim 1 wherein the limiter circuit comprises a passive circuit element.

3. The circuit topology of claim 2 wherein the passive circuit element is a resistor.

4. The circuit topology of claim 1 wherein the limiter circuit comprises an active circuit element.

5. The circuit topology of claim 4 wherein the active circuit element is a diode having a cathode coupled to the first gate and an anode coupled to the second source.

6. The circuit topology of claim 5 wherein the diode is a silicon diode.

7. The circuit topology of claim 4 wherein the active circuit element is a plurality of diodes coupled in series between the first gate and the second source such that a total forward voltage drop of the plurality of diodes constrains the gate-to-source voltage of the normally-on transistor to a value that limits a drain current flowing through the normally-off transistor to a predetermined value when the normally-off transistor is turned on.

8. The circuit topology of claim 7 wherein the plurality of diodes is two silicon diodes coupled in series.

9. The circuit topology of claim 1 wherein the normally-on transistor is a gallium nitride (GaN) technology device.

10. The circuit topology of claim 1 wherein the normally-off transistor is a GaN technology device.
